(19) United States
(12) Patent Application Publication
(10) Pub. No.: US 2026/0031162 A1
(43) Pub. Date: Jan. 29, 2026

(54) REUSING PARTIALLY CORRUPTED MEMORY BLOCKS

(71) Applicant: Microchip Technology Incorporated, Chandler, AZ (US)

(72) Inventors: Pitamber SHUKLA, San Jose, CA (US); Nian Niles YANG, Mountain View, CA (US)

(21) Appl. No.: 19/007,468

(22) Filed: Dec. 31, 2024

Related U.S. Application Data
(60) Provisional application No. 63/676,901, filed on Jul. 29, 2024.

(51) Int. Cl. G11C 16/34; G11C 16/10; G11C 16/26

(52) U.S. Cl. CPC G11C 16/3445; G11C 16/102; G11C 16/26

(57) ABSTRACT

A controller may perform an erase operation on a block of a non-volatile memory device. The block has been identified as a corrupted block. The erase operation is performed after a write operation. The controller may determine whether the erase operation is successful. The controller may perform a programming operation on the block to write random data on an entirety of the block. The controller may determine whether the programming operation is successful for a portion of the block. The controller may perform a read operation on the portion of the block. The controller may determine whether the read operation is successful. The controller may determine that the block is a partially corrupted block based on determining whether the read operation is successful. The portion of the block is an uncorrupted portion that is used for a subsequent programming operation of the block.

### CROSS-REFERENCE TO RELATED APPLICATION

This patent application claims priority to Provisional Patent Application No. 63/676,901, filed on Jul. 29, 2024, and entitled “IDENTIFYING AND PERFORMING PROGRAMMING OPERATIONS ON PARTIALLY CORRUPTED MEMORY BLOCKS OF VIRTUAL BLOCKS.” The disclosure of the prior Application is considered part of and is incorporated by reference into this patent application.

### FIELD

The present disclosure generally relates to partially corrupted memory blocks of non-volatile memory devices and, for example, to performing programming operations on partially corrupted memory blocks.

### BACKGROUND

A non-volatile memory device may include a storage device that may store and retain data without external power supply. One example of a storage device is a NAND flash memory device. A solid state drive (SSD) may include multiple non-volatile memory devices. A non-volatile memory device (or a die of the non-volatile memory device) may include multiple planes. A plane may include multiple blocks and a block may include multiple wordline. A wordline may include one or more pages.

Typically, a reliability of the SSD decreases as the age of the non-volatile memory devices increases. The decrease in reliability leads to an increase in read errors.

### SUMMARY

A method may comprise performing an erase operation on a block of a non-volatile memory device, wherein the block has been identified as a corrupted block, and wherein the erase operation is performed after a write operation; determining whether the erase operation is successful; performing a programming operation on the block to write random data on an entirety of the block; determining whether the programming operation is successful for a portion of the block; performing a read operation on the portion of the block; determining whether the read operation is successful; and determining that the block is a partially corrupted block based on determining whether the read operation is successful, wherein the portion of the block is an uncorrupted portion that is used for a subsequent programming operation of the block.

A system may comprise: a controller to: perform a programming operation on a block to write random data on an entirety of the block, wherein the block has been identified as a corrupted block; determine, based on performing the programming operation, that the block includes a corrupted portion and an uncorrupted portion; perform a read operation on the corrupted portion of the block; determine that the read operation is successful; determine that the block is a partially corrupted block based on determining that the read operation is successful; and perform a subsequent programming operation on the uncorrupted portion.

A non-transitory computer-readable medium storing a set of instructions, the set of instructions may comprise: one or more instructions that, when executed by one or more processors of a controller, cause the controller to: perform a programming operation on a block to write random data on an entirety of the block, wherein the block has been identified as a corrupted block; determine, based on performing the programming operation, that the block includes a corrupted portion and an uncorrupted portion; perform a read operation on the corrupted portion of the block; determine that the read operation is successful; determine that the block is a partially corrupted block based on determining that the read operation is successful; and perform a subsequent programming operation on the uncorrupted portion.

### BRIEF DESCRIPTION OF THE DRAWINGS

FIG. 1A is a block diagram showing an example of an SSD.

FIG. 1B illustrates a graph showing the relationship between threshold voltage and number of cells for different logic levels in a memory device and showing a program disturbance.

FIG. 2 is a diagram illustrating an example SSD 200 in accordance with implementations described herein.

FIG. 3 is a flowchart of an example process associated with identifying and programming a partially corrupted block.

FIG. 4 illustrates a flowchart of a process for identifying and programming a partially corrupted memory block based on determining whether a read operation is successful.

### DETAILED DESCRIPTION

The following detailed description of example implementations refers to the accompanying drawings. The same reference numbers in different drawings may identify the same or similar elements.

A solid state drive (SSD) may provide data regarding the SSD to a host device associated with the SSD. A solid state drive (SSD) may include multiple non-volatile memory devices. The multiple non-volatile memory devices (or dies of the multiple non-volatile memory devices) may include multiple planes. A plane may include multiple blocks (or memory blocks) and a block may include multiple wordlines.

In some situations, a non-volatile memory device may include partially corrupted blocks (or bad blocks). A partially corrupted block may refer to a block that is subjected to read errors or program (or write) errors. In some situations, the read errors and write errors may be caused by a portion of wordlines (of the non-volatile memory device) subject to defects. The defects may include wordline to wordline shorts, wordline to channel shorts, and wordline to source shorts, among other examples. Wordline to wordline shorts may be caused by one or more particles which bridge two or more wordlines.

With respect to wordline to wordline shorts as an example, during a program operation, the wordline to wordline short may cause a drop (or reduction) in a program voltage at a targeted wordline. The targeted wordline may refer to a wordline selected for the program operation. The drop in the program voltage may result in a program status failure of a next wordline and a program disturb on a previous wordline due to a maximum number of program operations for the targeted wordline. The wordline to wordline short (and other defects) may occur with respect to a portion of wordlines, not an entirety of the wordlines.

A defect occurring on a portion of wordlines may be referred to as a “localized defect.” A localized defect (in a block) may lead to read errors, program errors, or a combination of read errors and program errors. The read errors, program errors, or a combination of read errors and program errors may degrade a capacity of the non-volatile memory device and, accordingly, limit a lifetime of the non-volatile memory device.

The non-volatile memory device may include a partially corrupted block that is partially corrupted at the time the non-volatile memory device is manufactured. This partially corrupted block may be referred to as a “factory marked bad block.” Additionally, or alternatively, the non-volatile memory device may include a partially corrupted block that is partially corrupted as the non-volatile memory device is being utilized (e.g., partially corrupted as a result of read or write operations on the non-volatile memory device). This partially corrupted block may be identified as a corrupted block by a controller and may be referred to as a “on field firmware marked bad block.” In some situations, as the number of on field firmware marked bad blocks increases, the non-volatile memory device may operate in a read-only mode. In other words, the non-volatile memory device may not be capable of performing program operations to store new data because additional blocks may not be available to store the new data.

Currently, a system firmware (for the non-volatile memory device) does not attempt to recover and reuse any portion of the factory marked bad blocks and any portion of the on-field firmware marked bad blocks after the system firmware (e.g., the controller) detects read or program errors. In other words, when the system firmware detects read or programs errors of a block, the block is identified as a corrupted block and is no longer used to store data. Existing overprovisioning (OP) and block management firmware solutions are non-adaptive. In other words, existing OP and block management firmware solutions do not take into account the fact that the read and program errors may be caused by a portion of wordlines. Accordingly, existing OP and block management firmware solutions are prone to system yield loss caused by not using blocks that are identified as corrupted blocks. The system yield loss may significantly reduce the lifetime of the non-volatile memory device.

To mitigate system yield loss, spare blocks are typically allocated to maintain the capacity of the non-volatile memory device and to accommodate garbage collection operations. However, this strategy can increase the overall cost of the non-volatile memory device and can reduce the lifespan of the non-volatile memory device. Without an effective management solution for partially corrupted blocks, the capacity of the non-volatile memory device may not be fully utilized.

The present disclosure provides such a technical solution to address the aforementioned problems. For example, implementations described herein are directed to reclaiming factory marked bad blocks and on field firmware marked bad blocks. In some examples, “reclaiming a bad block” may refer to using or reusing one or more portions of wordlines (of a partially corrupted block) that are not subjected to defects. By reclaiming bad blocks, implementations described herein will significantly improve a block budget for a non-volatile memory device and, therefore, will enhance a lifetime of the non-volatile memory device at a reduced cost. The block budget may refer to an allocation of blocks for overprovisioning purposes and for garbage collection operations. The non-volatile memory device may be included in an SSD. By reclaiming bad blocks, implementations described herein will address the limitation of the current system firmware limitation with respect to corrupted blocks.

Implementations described herein provide an algorithm for selective recovery and usage of partially corrupted blocks from a pool of factory marked bad blocks and on field firmware marked bad block. The algorithm selectively recovers and uses partially corrupted blocks based on dummy operations, such as dummy erase operations, dummy program operations, and dummy read status check. The dummy operations may be performed as part of background operations performed on the non-volatile memory device. The dummy operations may be initiated by a controller of an SSD independent of a command issued by a host device associated with the SSD. In contrast, regular/non-dummy operations may be initiated by the controller based on commands issued by the host device. For example, the controller may initiate a regular/non-dummy erase operation based on an erase command issued by the host device. Similarly, the controller may initiate a regular/non-dummy program operation based on a program command issued by the host device. In contrast to dummy operations, regular/non-dummy operations may be performed as part of foreground operations. Various implementations described herein offer a technical solution for using or reusing partially corrupted blocks. These implementations may enhance the lifespan of an SSD and may reduce associated costs by improving the management of blocks in non-volatile memory.

In some examples, when using a partially corrupted block, the controller may skip the corrupted portion and use the uncorrupted portion for data storage. For instance, corrupted portions may include wordlines affected by defects, such as wordline-to-wordline shorts caused by particles bridging the wordlines. During the programming of a target wordline, such shorts can reduce the programming voltage, leading to program failure in subsequent wordlines and program disturbances in previous wordlines due to additional programming cycles.

The uncorrupted wordlines may refer to wordlines that are not affected by defects. The uncorrupted wordlines may be used (as intended) for data storage. Programming and erase operations may be performed on the uncorrupted wordlines under conditions that are more conducive to the endurance of the SSD and/or the data retention of the SSD. The conditions may include NAND trim conditions.

In some cases, wordlines in corrupted portions may be programmed with padding data, which may consist of either fixed patterns (e.g., 00h) or random data generated by the controller. This padding data may not be accessible to a user of the SSD but may be managed entirely by the controller. When programming this padding data, the controller may skip a program verification operation to streamline the process of programming the padding data.

By using or reusing partially corrupted blocks, implementations described herein enhance SSD capacity, improve system yield as the SSD ages, and optimize garbage collection block management. By using or reusing partially corrupted blocks, implementations described herein assist with urgent garbage collection when the SSD is full (e.g., when the SSD has stored data up to a storage capacity of the SSD). Accordingly, the controller may provide a technical solution to the technical problems described herein.

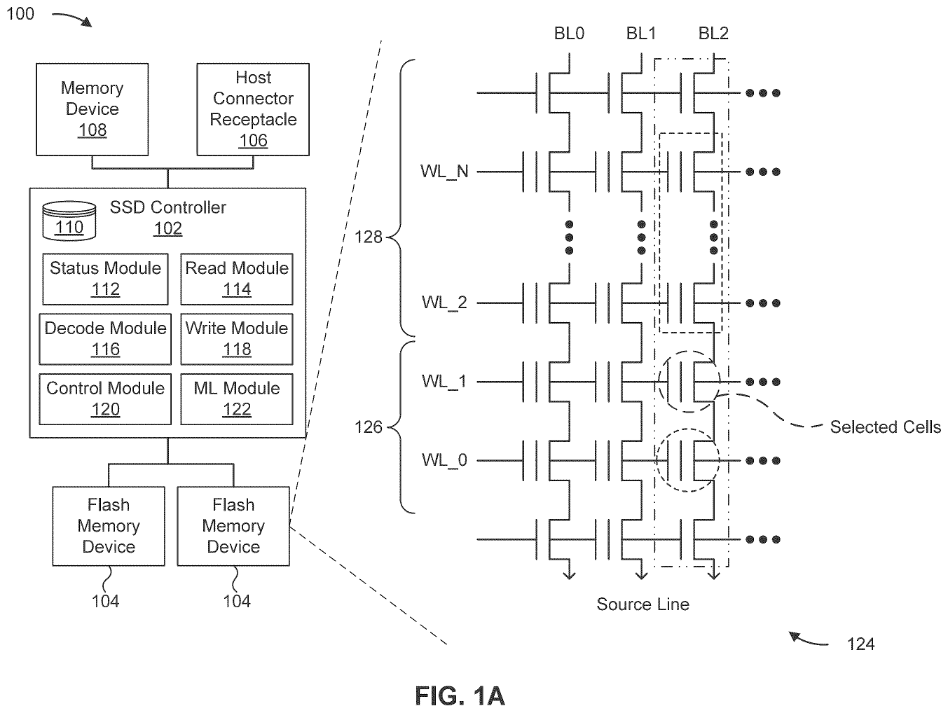

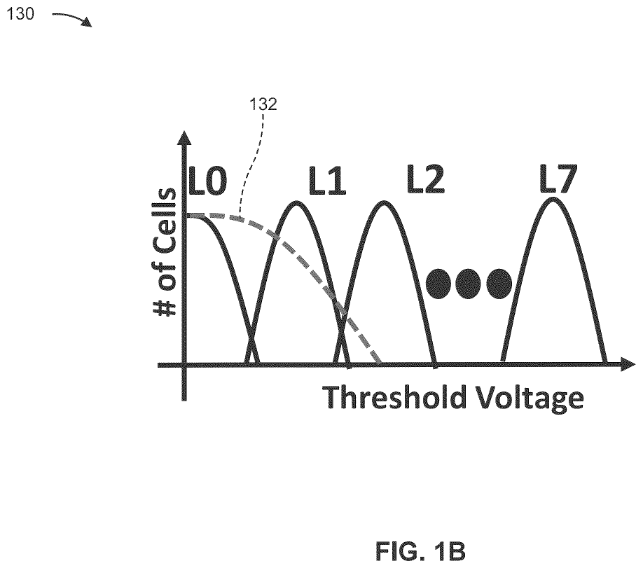

FIG. 1A is a block diagram showing an example of an SSD 100, in accordance with the present disclosure. SSDs may use standard read instructions (e.g., a READ or READ PAGE instruction) to perform a read of a memory cell at a default threshold voltage within a threshold voltage region defining a bit of the memory cell. Single Level Cell (SLC) flash memory devices store a single bit of information in each cell and only require a read in a single threshold voltage region (the threshold voltage region is the region that extends between the center of the voltage distribution for a 1 and the center of the voltage distribution for a 0) to identify the value of a bit (whether the cell is storing a 1 or a 0). Multi-level cell (MLC) flash memory devices store two bits of information in each cell, triple level cell (TLC) flash memory devices store three bits of information in each cell, quad level cell (QLC) flash memory devices store four bits of information in each cell and penta level cell (PLC) flash memory devices store five bits of information in each cell.

Some SSDs use threshold-voltage-shift reads for reading flash memory devices to obtain low levels of Uncorrectable Bit Error Rate (UBER) required for client and enterprise SSD's. Threshold-voltage-shift reads are performed by sending a threshold-voltage-shift read instruction to a flash memory device that is to be read. One or more threshold-Voltage-Shift Offset (TVSO) values are sent with the threshold-voltage-shift read instruction. The TVSO value indicates the amount by which the threshold voltage that is used to perform the read is to be offset from a corresponding default threshold voltage that is specified by the manufacturer of the flash memory device. Threshold-voltage-shift read instructions for MLC, TLC, QLC and PLC flash memory devices require that multiple TVSO values be sent to the flash memory device in order to perform each read.

The SSD 100 is shown in FIG. 1A to include an SSD controller 102 coupled to a plurality of flash memory devices 104 for storing data. In some embodiments, the flash memory devices 104 are NAND devices and the SSD 100 includes one or more circuit boards onto which a host connector receptacle 106, the SSD controller 102, and the flash memory devices 104 are attached. The SSD 100 may also include one or more memory devices 108, such as a Dynamic Random Access Memory (DRAM), that may be a separate integrated circuit device attached to the one or more circuit boards, and is electrically coupled to the SSD controller 102.

The SSD controller 102 is configured to receive read and write instructions from a host computer through the host connector receptacle 106, and to perform program operations, erase operations, and read operations on memory cells of flash memory devices 104 to complete the instructions from the host computer. For example, upon receiving a write instruction from the host computer via host connector receptacle 106, the SSD controller 102 is operable to store data in the SSD 100 by performing program operations (and when required, erase operations) to program codewords into on one or more flash memory devices 104. As used herein, a codeword may refer to information that may be used to encode and correct errors in data stored on one or more flash memory devices 104.

The SSD controller 102 includes a data storage module 110, a status module 112, a read module 114, a decode module 116, a write module 118, a control module 120, and a machine learning (ML) module 122. The control module 120 may be coupled to the data storage module 110, the status module 112, the read module 114, the decode module 116, the write module 118, and the ML module 122. The status module 112 may be coupled to the data storage module 110, the read module 114, the decode module 116, the write module 118, the control module 120, and the ML module 122. The data storage module 110 may store configuration files associated with the ML module 122 and/or a TVSO selection table, among other examples. A TVSO selection table may be coupled to the read module 114. A TVSO selection table may include one or more indexes and corresponding TVSO values to be used in performing reads (e.g., an index corresponding to a block, a wordline or a page and TVSO values for each threshold voltage region required to perform a read).

The read module 114 may be coupled to the control module 120, the ML module 122, and the decode module 116. The control module 120 may be coupled to the decode module 116, the ML module 122, and the data storage module 110. The ML module 122 may be coupled to data storage module 110 such that configuration files can be loaded thereon. In some examples, the ML module 122 may include a neural processing module such as, for example, a specialized hardware module (e.g., a specialized configurable accelerator) specifically configured to perform neural network operations, sometimes referred to as a neural network engine (e.g., a programmable logic circuit). In some examples, the ML module 122 may include firmware (e.g., a processor and software for performing ML operations).

In some implementations, the SSD controller 102 may be an integrated circuit device; some or all of the modules 112, 114, 116, 118, 120, and 122 may include circuits that may be dedicated circuits for performing operations; and some or all of modules 112, 114, 116, 118, 120, and 122 may be firmware that include instructions that are performed on one or more processors for performing operations of the SSD controller 102, with the instructions stored in registers of one or more of modules 112, 114, 116, 118, 120, and 122 and/or stored in the data storage module 110 or the memory device 108. In some embodiments, some or all of modules 112, 114, 116, 118, 120, and 122 may include processors for performing instructions and one or more firmware image may be loaded into the SSD controller 102 (e.g., through the host connector receptacle 106) prior to operation of the SSD controller 102. The firmware image may include instructions to be performed by one or more of modules 112, 114, 116, 118, 120, and 122. Each flash memory device 104 may be a packaged semiconductor die or “chip” that is coupled to the SSD controller 102 by conductive pathways that couple instructions, data, and other information between each flash memory device 104 and the SSD controller 102.

As is further shown in FIG. 1A, the flash memory devices 104 may include memory arrays 124. Each memory array includes multiple wordlines (shown as “WL_N” to “WL_0”) and multiple bitlines (shown as “BL0,” “BL1,” and “BL2”). In some aspects, the memory array 124 may be referred to as a block. In some cases, the block may be partially corrupted. For example, the partially corrupted block 124 may have been identified as a factory identified bad block or as a firmware identified bad block.

As shown in FIG. 1A, the partially corrupted block 124 can include one or more wordlines that may be subjected to defects, such as wordline to wordline shorts. For example, wordlines WL_0 and WL_1 may be shorted together. Accordingly, wordlines WL_0 and WL_1 may form a corrupted portion 126. A remaining portion of partially corrupted block 124 (e.g., remaining wordlines WL_2-WL_N) may form an uncorrupted portion 128.

FIG. 1B illustrates a graph 130 showing the relationship between threshold voltage and number of cells for different logic levels in a memory device (e.g., a memory array 124). The graph 130 includes multiple bell-shaped curves representing threshold voltages, each corresponding to a different charge states labeled as L0, L1, L2, and L7.

In FIG. 1B, a threshold voltage of wordline WL_0 as a result of wordline WL_0 being subjected to an amount of program disturbance. As shown, a threshold voltage 132 of a targeted wordline WL_1 may drop as a result of the targeted wordline WL_1 experiencing a program status failure. The program status failure may be caused by a wordline to wordline short among other defects, as explained herein.

In some implementations, the uncorrupted portion 128 may be used for subsequent programming operations (e.g., to write user data). As explained herein, the corrupted portion 126 may be skipped and not be used for the subsequent programming operations to write user data. However, padding data may be written to corrupted portion 126 during the subsequent programming operations.

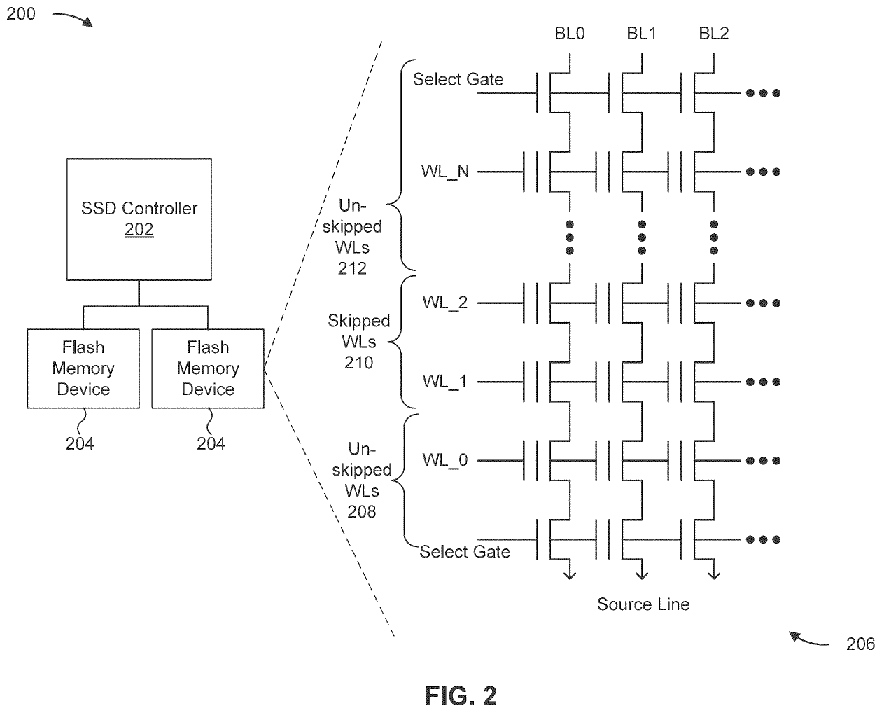

FIG. 2 is a diagram illustrating an example SSD 200 in accordance with implementations described herein. The SSD 200 includes an SSD controller 202 connected to multiple flash memory devices 204. Each flash memory device 204 contains a memory array 206. In some implementations, the SSD 200 may be, be similar to, include, or be included in the SSD 100 depicted in FIG. 1A.

The memory array 206 is depicted in detail, showing its structure of wordlines and bitlines. The wordlines include unskipped wordlines 208, skipped wordlines 210, and unskipped wordlines 212. The skipped wordlines 210 represent a portion of the memory array (e.g., a portion of wordlines) that may be corrupted or unusable, while the unskipped wordlines 208 and the unskipped wordlines 212 represent the portion that remains functional and can be used for data storage.

In this implementation, the memory array 206 is organized with multiple bitlines (BL0, BL1, BL2) intersecting with wordlines (WL_0, WL_1, WL_2, . . . , WL_N). Select gates are shown at both ends of the bitlines, controlling access to the memory cells. The source line is depicted at the bottom of the array, providing a common source connection for the memory cells. This configuration allows the SSD 200 to utilize partially corrupted memory blocks by programming data to the unskipped wordlines 208 and the unskipped wordlines 212, while avoiding (or skipping) the skipped wordlines 210. This approach enables more efficient use of storage capacity in situations where portions of memory blocks have become corrupted or unreliable.

The SSD controller 202 is configured to identify partially corrupted blocks and manage the programming operations accordingly. When a block is identified as partially corrupted, the controller 202 determines which wordlines are to be skipped (corrupted wordlines) and which are to be unskipped and programmed (uncorrupted wordlines). This determination may be based on various factors, such as program failures, read errors, or other reliability indicators. During subsequent programming operations, the controller 202 directs user data to be written only to the unskipped wordlines 208 and 212. This ensures that data is stored in reliable portions of the memory array. For example, wordlines WL_1 and WL_2 are identified as corrupted. As such, they are designated as skipped wordlines 210, and the controller 202 would not use them for storing user data.

To maintain block consistency and potentially improve reliability, the controller 202 may program padding data to the skipped wordlines 210. This padding data can take various forms, such as a fixed pattern (e.g., all 0s or all 1s) or a random pattern generated by the controller. The padding data is not intended to store user information and is not accessible by the host system. The process of programming padding data to skipped wordlines 208 may differ from normal programming operations. For instance, the controller 202 may use modified voltage levels or timing parameters when writing to these corrupted areas. Additionally, the controller may skip the program verify operation for the padding data, as the exact contents of this data is unimportant and, thus, does not need to be verified.

By implementing this approach, the SSD 200 can achieve several advantages. First, it may allow for the utilization of partially corrupted blocks that would otherwise be marked as entirely corrupted and unusable. This can improve the overall capacity and lifespan of the SSD 200, especially as the device ages and more blocks develop partial corruptions. Second, this technique can reduce the amount of spare blocks that would have otherwise been allocated due to system yield loss caused by not reusing partially corrupted blocks. The programming of padding data to these areas can also help maintain more consistent electrical characteristics across the block, potentially mitigating some of the negative effects associated with partially programmed blocks. Third, this approach can improve the efficiency of garbage collection processes. When the SSD 200 needs to perform garbage collection, it can more easily identify and work with the valid data stored in the unskipped wordlines 208 and the unskipped wordlines 212, without needing to manage or relocate data from the corrupted areas.

The SSD 200 may also incorporate adaptive techniques to optimize the use of partially corrupted blocks over time. For example, the controller 202 may periodically reassess the health of skipped wordlines 210 to determine if any have become usable. Conversely, it may also monitor the unskipped wordlines 208 and the unskipped wordlines 212 for signs of degradation, potentially reclassifying them as skipped wordlines (or corrupted wordlines) if their reliability decreases. In some implementations, the controller 202 may employ machine learning algorithms to predict which wordlines are likely to become corrupted based on various factors such as program/erase cycle count, error rates, and voltage shift characteristics. This predictive approach could allow the SSD to proactively manage potentially problematic areas before they lead to data loss or significant performance degradation.

Overall, the SSD 200, with its ability to manage partially corrupted blocks, may provide a technical solution to the problem of decreasing reliability and capacity in aging SSDs. By intelligently utilizing the uncorrupted portions of blocks and managing the corrupted portions, this system can extend the useful life of the SSD 200, maintain higher effective capacities, and ensure more consistent performance over time.

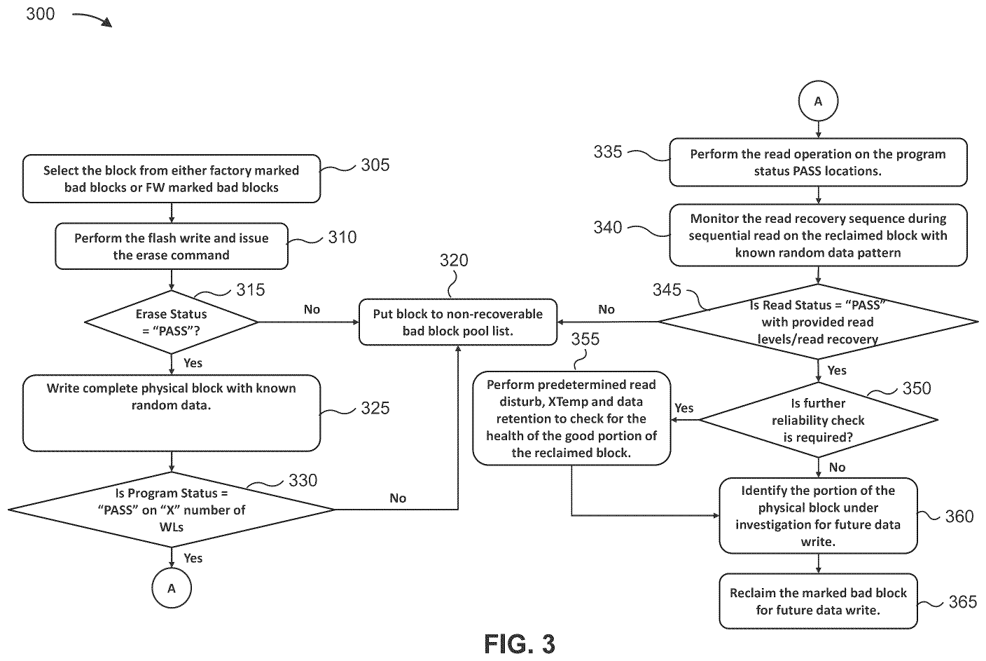

FIG. 3 illustrates a flowchart of a technique 300 for identifying and utilizing partially corrupted memory blocks. The technique 300 may be performed by an SSD controller such as, for example, the SSD controller 202 shown in FIG. 2 and/or the SSD controller 102 shown in FIG. 1A.

The technique 300 begins with block 305, where a block is selected from either factory marked bad blocks or firmware marked bad blocks (or on field firmware marked bad block). A “factory marked bad block” may refer to a partially corrupted block that is partially corrupted at the time a non-volatile memory device (including the partially corrupted block) is manufactured. A “firmware marked bad block” may include a partially corrupted block that is partially corrupted as the non-volatile memory device is being utilized (e.g., partially corrupted as a result of read or write operations on the non-volatile memory device). This initial selection process allows the system to focus on blocks that have been previously identified as potentially problematic, either during manufacturing or through firmware operations, such as read operations and program operations. In block 310, a flash write operation is performed and an erase command is issued. Block 310 may prepare the block for assessment and potential reclamation. The flash write operation ensures that the block is in a known state before the erase command is applied.

Block 315 involves determining if the erase status is “PASS”. If the erase status is not “PASS” (“No” branch—a failure of an erase operation), the technique 300 moves to block 320, where the block is put into a non-recoverable bad block pool list. This ensures that blocks that fail the erase operation are properly segregated and not used for future data storage. If the erase status is “PASS” (“Yes” branch—an erase operation that is successful), the technique 300 proceeds to block 325, where a complete physical block is written with known random data (e.g., padding data). This block may facilitate assessing the block's ability to hold data reliably across all its cells.

At 330, the technique 300 involves checking if the program status is “PASS” on “X” number of wordlines. The value of “X” may be predetermined based on system requirements, may be based on historical data regarding the number of wordlines evaluated, or may be dynamically adjusted. If the program status is not “PASS” on the number of wordlines (“No” branch), the technique returns to block 320, marking the block as non-recoverable. This ensures that only blocks with a sufficient number of functional wordlines are considered for reclamation (e.g., considered for reuse). If the program status is “PASS” on the required number of wordlines (“Yes” branch), the technique 300 moves to block 335, where a read operation is performed on the program status “PASS” locations. This block verifies that the data written in block 325 can be accurately read back. In some implementations, remaining wordlines may be identified as corrupted. The “remaining wordlines” may refer to wordlines other than the number of functional wordlines that are being considered for reuse.

In block 340, the technique 300 involves monitoring the read recovery sequence during a sequential read on the reclaimed block with the known random data pattern. This block facilitates assessing the reliability of the read operations on the potentially reclaimed block. At 345, the technique 300 includes determining if the read status is “PASS” with provided read levels/read recovery. With respect to read levels for example, the technique 300 includes determining whether data was successfully read using one or more threshold voltages used to perform the read operations. In some examples, the threshold voltages may be pre-determined (or pre-selected) threshold voltages. For instances, the threshold voltages may be threshold voltages that have been pre-determined (or pre-selected) to perform read operations to determine whether a partially block may be reclaimed. In some examples, the threshold voltages may be pre-determined (or pre-selected) by a manufacturer of the nonvolatile memory device that includes the partially corrupted block. With respect to read recovery for example, the technique 300 includes determining whether data was successfully recovered (or retrieved using one or more data recovery (or retrieval) techniques. The one or more data recovery (or retrieval) techniques may include ready retry operations, error correction codes (ECC) operations, among other examples. A read retry operation may refer to performing multiple read operations (e.g., on a wordline or a memory cell) using varying threshold voltages. If not (“No” branch), the technique returns to block 320, marking the block as non-recoverable. This ensures that only blocks that can be reliably read are considered for reclamation.

If the read status is “PASS” (“Yes” branch), the technique 300 proceeds to block 350, which includes checking if a further reliability check is required. This decision may be based on various factors such as the block's history, the number of program/erase cycles, or system-wide reliability targets. If a further reliability check is required (“Yes” branch), block 355 is performed, involving performing predetermined read disturb, cross temperature, and data retention checks to assess the health of the good portion of the reclaimed block. These additional checks provide a more comprehensive evaluation of the block's reliability under various conditions. The technique then moves to block 360. If no further reliability check is required (“No” branch from block 350), the technique 300 proceeds directly to block 360.

Block 360 involves identifying the portion of the physical block under investigation for future data writes. For example, block 360 may involve identifying one or more wordlines that are corrupted and are to be skipped during a program operation (e.g., to program user data). This block may facilitate determining which parts of the partially corrupted block can be safely used for data storage. Finally, at 365, the marked bad block is reclaimed for future data writes. This block effectively adds the partially corrupted block back into the pool of usable storage, albeit with limitations on which portions can be used.

In some implementations, the technique 300 provides a structured approach to assess and potentially reclaim partially corrupted memory blocks, allowing for more efficient use of storage capacity in non-volatile memory devices. By carefully evaluating each block through a series of write, erase, and read operations, the system can confidently determine which portions of a block are still reliable for data storage. This technique aligns with the claims of the disclosure by implementing a method to identify partially corrupted blocks and determine which portions can be safely used for subsequent programming operations. It addresses the technical problem of decreasing storage capacity in aging SSDs by providing a means to reclaim and utilize portions of blocks that would otherwise be completely discarded.

In some implementations, the technique also incorporates reliability checks and monitoring of read recovery sequences, which are mentioned in dependent claims. These operations ensure that the reclaimed portions of blocks meet the necessary reliability standards for data storage. By implementing this technique, an SSD can potentially extend its usable life and maintain higher effective capacities over time. This aligns with the overall goal of the disclosure to improve the efficiency and longevity of non-volatile memory devices.

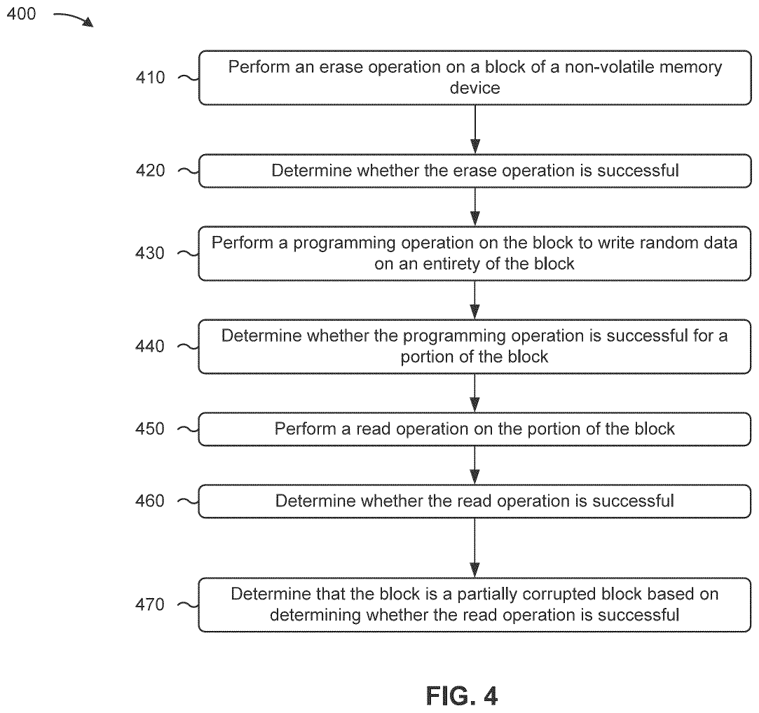

FIG. 4 illustrates a flowchart of a technique 400 for identifying and programming a partially corrupted memory block. The technique 400 may be performed by an SSD controller such as, for example, the SSD controller 202 shown in FIG. 2 and/or the SSD controller 102 shown in FIG. 1A.

The technique 400 includes performing an erase operation on a block of a non-volatile memory device (block 410). For example, the controller may perform an erase operation on a block of a non-volatile memory device, as described above in connection with block 310. This block has been previously identified as a corrupted block, either through factory marking or firmware identification. This erase operation is performed after a write operation, which helps to prepare the block for assessment.

The technique 400 further includes determining whether the erase operation is successful (block 420). For example, the controller may determine whether the erase operation is successful, as described above in connection with block 315. For example, this determination may provide an initial indication of the block's overall health. A successful erase operation suggests that at least some portions of the block may still be usable.

If the erase operation is successful, the technique 400 moves to block 430, where a programming operation is performed on the block to write random data on an entirety of the block. For example, the controller may perform a programming operation on the block to write random data on an entirety of the block, as described above in connection with block 325. This serves to test the block's ability to hold data across all its cells.

The technique 400 then proceeds to block 440, where it determines whether the programming operation is successful for a portion of the block. For example, the controller may determine whether the programming operation is successful for a portion of the block, as described above in connection with block 330. This may facilitate identifying which parts of the block, if any, are still functional and can be used for data storage.

Following this, the technique 400 includes performing a read operation on the portion of the block that was successfully programmed at block 450. For example, the controller may perform a read operation on the portion of the block, as described above in connection with block 335. This read operation serves to verify that the data written at block 430 can be accurately retrieved.

The technique 400 further involves determining whether the read operation is successful (block 460). For example, the controller may determine whether the read operation is successful, as described above in connection with block 340. This may facilitate assessing the reliability of the potentially usable portion of the block. At block 470, the technique 400 includes determining that the block is a partially corrupted block based on the success of the read operation. For example, the controller may determine that the block is a partially corrupted block based on determining whether the read operation is successful, as described above in connection with block 350. In some examples, if a particular portion of the block has failed a programming operation, then the particular portion will also fail a read operation. Nevertheless, the portion of the block that has passed the programming will undergo a read check operation to further confirm that the portion may be used for a programming operation. The portion of the block is an uncorrupted portion that is used for a subsequent programming operation of the block, as described above. This may involve determining which portions of the block can be used for subsequent programming operations. In some implementations, the portion of the block is an uncorrupted portion that is used for a subsequent programming operation of the block. In some implementations, the block includes a corrupted portion that is not used during the subsequent programming operation.

In some implementations, the block includes a corrupted portion that is not used during the subsequent programming operation, and wherein the method further comprises programming padding data on the corrupted portion during the subsequent programming operation. In some implementations, the block includes a corrupted portion that is not used during the subsequent programming operation, and wherein the method further comprises programming padding data on the corrupted portion during the subsequent programming operation. In some implementations, the padding data includes data of a fixed pattern, and wherein the padding data includes data of a random pattern. In some implementations, technique 400 includes including the block in a pool of non-recoverable blocks when the erase operation is not successful, or including the block in a pool of non-recoverable blocks when the programming operation is not successful for the portion of the block.

In some implementations, the technique 400 includes monitoring a read recovery sequence during a sequential read associated with performing the read operation on the portion of the block. In some implementations, the technique 400 includes determining that the read operation is successful, and determining whether a reliability check is to be performed on the block when the read operation is successful. In some implementations, the technique 400 includes performing the reliability check to determine a health of the portion of the block, wherein performing the reliability check includes predetermined read disturb, cross temperature, and a data retention.

The technique 400 provides a method for identifying partially corrupted blocks and determining which portions can be safely used for future data storage. This technique 400 addresses the technical problem of decreasing storage capacity in aging SSDs by providing a means to reclaim and utilize portions of blocks that would otherwise be completely discarded. By doing so, implementations of the technique 400 can help extend the usable life of an SSD and maintain higher effective capacities over time.

The technique 400 also may be extended to include programming of padding data on corrupted portions during subsequent operations. The technique 400 also provides a framework for implementing reliability checks and monitoring read recovery sequences. By implementing aspects of the technique 400, an SSD controller can effectively manage partially corrupted blocks, leading to improved storage utilization and potentially extended device lifespan. In this way, aspects of the technique 400 may facilitate enhancing the efficiency and longevity of non-volatile memory devices.

Although FIG. 4 shows example blocks of technique 400, in some implementations, technique 400 may include additional blocks, fewer blocks, different blocks, or differently arranged blocks than those depicted in FIG. 4. Additionally, or alternatively, two or more of the blocks of technique 400 may be performed in parallel.

In some implementations, a method comprising: performing an erase operation on a block of a non-volatile memory device, wherein the block has been identified as a corrupted block, and wherein the erase operation is performed after a write operation; determining whether the erase operation is successful; performing a programming operation on the block to write random data on an entirety of the block; determining whether the programming operation is successful for a portion of the block; performing a read operation on the portion of the block; determining whether the read operation is successful; determining that the block is a partially corrupted block based on determining whether the read operation is successful, wherein the portion of the block is an uncorrupted portion that is used for a subsequent programming operation of the block.

In some implementations, a system comprising: a controller to: perform a programming operation on a block to write random data on an entirety of the block, wherein the block has been identified as a corrupted block; determine, based on performing the programming operation, that the block includes a corrupted portion and an uncorrupted portion; perform a read operation on the corrupted portion of the block; determine that the read operation is successful; determine that the block is a partially corrupted block based on determining that the read operation is successful; and perform a subsequent programming operation on the uncorrupted portion.

In some implementations, a non-transitory computer-readable medium storing a set of instructions includes one or more instructions that, when executed by one or more processors of a controller, cause the controller to: perform a programming operation on a block to write random data on an entirety of the block, wherein the block has been identified as a corrupted block; determine, based on performing the programming operation, that the block includes a corrupted portion and an uncorrupted portion; perform a read operation on the corrupted portion of the block; determine that the read operation is successful; determine that the block is a partially corrupted block based on determining that the read operation is successful; and perform a subsequent programming operation on the uncorrupted portion.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

As used herein, the term “component” is intended to be broadly construed as hardware, firmware, or a combination of hardware and software. It will be apparent that systems or methods described herein may be implemented in different forms of hardware, firmware, or a combination of hardware and software. The actual specialized control hardware or software code used to implement these systems or methods is not limiting of the implementations. Thus, the operation and behavior of the systems or methods are described herein without reference to specific software code—it being understood that software and hardware can be used to implement the systems or methods based on the description herein.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Although particular combinations of features are recited in the claims or disclosed in the specification, these combinations are not intended to limit the disclosure of various implementations. In fact, many of these features may be combined in ways not specifically recited in the claims or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item. No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “or,” unless explicitly stated otherwise (e.g., if used in combination with “either” or “only one of”).

What is claimed is:

1. A method comprising:
performing an erase operation on a block of a non-volatile memory device,
wherein the block has been identified as a corrupted block, and
wherein the erase operation is performed after a write operation;
determining whether the erase operation is successful;
performing a programming operation on the block to write random data on an entirety of the block;
determining whether the programming operation is successful for a portion of the block;
performing a read operation on the portion of the block;
determining whether the read operation is successful; and
determining that the block is a partially corrupted block based on determining whether the read operation is successful,
wherein the portion of the block is an uncorrupted portion that is used for a subsequent programming operation of the block.

2. The method of claim 1, wherein the block includes a corrupted portion that is not used during the subsequent programming operation.

3. The method of claim 1, wherein the block includes a corrupted portion that is not used during the subsequent programming operation, and
wherein the method further comprises:
programming padding data on the corrupted portion during the subsequent programming operation.

4. The method of claim 3, wherein the padding data includes data of a fixed pattern, and
wherein the padding data includes data of a random pattern.

5. The method of claim 1, comprising:
including the block in a pool of non-recoverable blocks when the erase operation is not successful; or
including the block in a pool of non-recoverable blocks when the programming operation is not successful for the portion of the block.

6. The method of claim 1, comprising:
monitoring a read recovery sequence during a sequential read associated with performing the read operation on the portion of the block.

7. The method of claim 6, comprising:
determining that the read operation is successful; and
determining whether a reliability check is to be performed on the block when the read operation is successful.

8. The method of claim 7, comprising:
performing the reliability check to determine a health of the portion of the block,
wherein performing the reliability check includes predetermined read disturb, cross temperature, and a data retention.

9. A system comprising:
a controller to:
perform a programming operation on a block to write random data on an entirety of the block,
wherein the block has been identified as a corrupted block;
determine, based on performing the programming operation, that the block includes a corrupted portion and an uncorrupted portion;
perform a read operation on the corrupted portion of the block;
determine that the read operation is successful;
determine that the block is a partially corrupted block based on determining that the read operation is successful; and
perform a subsequent programming operation on the uncorrupted portion.

10. The system of claim 9, wherein the corrupted portion is not used during the subsequent programming operation.

11. The system of claim 9, wherein the controller is to:
program padding data on the corrupted portion during the subsequent programming operation.

12. The system of claim 11, wherein the padding data includes data of a fixed pattern.

13. The system of claim 11, wherein the padding data includes data of a random pattern.

14. The system of claim 9, wherein the controller is to:
monitor a read recovery sequence during a sequential read associated with performing the read operation on the corrupted portion of the block.

15. The system of claim 9, wherein the controller is to:
perform a reliability check on the uncorrupted portion to determine a health of the uncorrupted portion.

16. A non-transitory computer-readable medium storing a set of instructions, the set of instructions comprising:
one or more instructions that, when executed by one or more processors of a controller, cause the controller to:
perform a programming operation on a block to write random data on an entirety of the block,
wherein the block has been identified as a corrupted block;
determine, based on performing the programming operation, that the block includes a corrupted portion and an uncorrupted portion;
perform a read operation on the corrupted portion of the block;
determine that the read operation is successful;
determine that the block is a partially corrupted block based on determining that the read operation is successful; and
perform a subsequent programming operation on the uncorrupted portion.

17. The non-transitory computer-readable medium of claim 16, wherein the corrupted portion is not used during the subsequent programming operation.

18. The non-transitory computer-readable medium of claim 16, wherein the one or more instructions further cause the controller to:
program padding data on the corrupted portion during the subsequent programming operation.

19. The non-transitory computer-readable medium of claim 18, wherein the padding data includes data of a fixed pattern, and
wherein the padding data includes data of a random pattern.

20. The non-transitory computer-readable medium of claim 16, wherein, to perform the subsequent programming operation, the controller is to:
write random data to an unprogrammed wordline; or
write predetermined data to an unprogrammed wordline.

21. The non-transitory computer-readable medium of claim 16, wherein the one or more instructions further cause the controller to:
monitor a read recovery sequence during a sequential read associated with performing the read operation on the corrupted portion of the block.

22. The non-transitory computer-readable medium of claim 16, wherein the one or more instructions further cause the controller to:
perform a reliability check on the uncorrupted portion to determine a health of the uncorrupted portion.
